(19) United States
(12) Patent Application Publication
(10) Pub. No.: US 2026/0353776 A1
(43) Pub. Date: Nov. 5, 2026

(54) EMBEDDED INTERCONNECTS IN SEMICONDUCTOR STRUCTURES

(71) Applicant: International Business Machines Corporation, Armonk, NY (US)

(72) Inventors: Kishwar Mashooq, Albany, NY (US); Shahrukh Khan, Sandy Hook, CT (US); Minhaz Abedin, Delmar, NY (US); Abir Shadman, Albany, NY (US); Sarah Nahar Chowdhury, Guilderland, NY (US)

(21) Appl. No.: 19/197,962

(22) Filed: May 2, 2025

(51) Int. Cl. H10D 84/83; H10D 84/01

(52) U.S. Cl. CPC H10D 84/8312; H10D 84/0149; H10D 84/0151; H10D 84/832

(57) ABSTRACT

A semiconductor structure includes a substrate; a first field effect transistor located on the substrate, the first field effect transistor having a first stack of nanosheets, a metal gate, a first source/drain region, and a second source/drain region; a second field effect transistor located on the first field effect transistor, the second field effect transistor having a second stack of nanosheets, the metal gate, a third source/drain region, and a fourth source/drain region; and a metalized embedded contact sandwiched between the first epitaxial layer of the first field effect transistor and the third epitaxial layer of the second field effect transistor. The metalized embedded contact filling a gap between the first source/drain region and the third source/drain region.

### BACKGROUND

The present invention relates to the electrical, electronic, and computer arts, and more specifically, to metal-oxide-semiconductor field-effect transistors, such as nanosheet transistors, and the like.

The metal-oxide-semiconductor field-effect transistor has a source, a drain, one or more channel regions, and a gate electrode, such as a metal oxide gate electrode. The metal gate is typically electrically insulated from the main semiconductor n-channel(s) or p-channel(s) by a thin layer of insulating material, for example, silicon dioxide or high dielectric constant (high-k) dielectrics, which make the input resistance of the metal-oxide-semiconductor field-effect transistor relatively high. The gate voltage controls whether the path from drain to source is an open circuit (“OFF”) or a resistive path (“ON”).

N-type field effect transistors and p-type field effect transistors are complementary metal-oxide-semiconductor field-effect transistors. The n-type field effect transistor uses electrons as current carriers and n-doped source and drain junctions. The p-type field effect transistor uses holes as current carriers and p-doped source and drain junctions.

As semiconductor devices scale to smaller dimensions (i.e., increase in cell height scaling), nanosheet (also known as nanowire) devices provide advantages. Stacked nanosheets can provide area efficiency. For example, stacked nanosheets provide increased drive current within a given layout area. Also, three-dimensional integration by vertically stacking n-type field effect transistors and p-type field effect transistors can be an advantageous approach as vertical stacking of n-type field effect transistors and p-type field effect transistors, combined with nanosheet technology, can benefit from device electrostatics control in addition to area scaling.

Over lateral devices, vertically stacked n-type field effect transistors and p-type field effect transistors can employ semiconductor channels with various gate-all-around technologies to achieve increased device density, greater power efficiency, and increased performance. In a gate-all-around device, the gate stack wraps around the full perimeter of each nanosheet, enabling fuller depletion in the channel region, and reducing short-channel effects due to steeper subthreshold swing and smaller drain induced barrier lowering. The wrap-around gate structures and source/drain contacts used in nanosheet-based devices also enable greater management of leakage current and parasitic capacitance in the active regions, including in applications with increased drive current. Nevertheless, there is a constant demand to improve the functionality of transistor circuitry.

### BRIEF SUMMARY

Principles of the invention provide techniques for embedded interconnects in semiconductor structures. In one aspect, an exemplary semiconductor structure, according to aspects of the invention, includes a substrate; a first field effect transistor located on the substrate, the first field effect transistor having a first stack of nanosheets, a metal gate, a first source/drain region, and a second source/drain region; a second field effect transistor located on the first field effect transistor, the second field effect transistor having a second stack of nanosheets, the metal gate, a third source/drain region, and a fourth source/drain region; and a metalized embedded contact sandwiched between the first source/drain region of the first field effect transistor and the third source/drain region of the second field effect transistor. The metalized embedded contact filling a gap between the first source/drain region and the third source/drain region.

In another aspect, an exemplary semiconductor structure includes a first field effect transistor including a first source/drain region, a second source/drain region, a first stack of nanosheets between the first source/drain region and the second source/drain region, and a metal gate surrounding the first stack of nanosheets; a second field effect transistor located on the first field effect transistor, the second field effect transistor including a third source/drain region, a fourth source/drain region, a second stack of nanosheets between the third source/drain region and the fourth source/drain region, and the metal gate surrounding the second stack of nanosheets; a metalized, fully embedded contact sandwiched between and directly contacting the first source/drain region of the first field effect transistor and the third source/drain region of the second field effect transistor, the metalized, fully embedded contact filling a gap between the first source/drain region and the third source/drain region; a first interlayer dielectric located between the second source/drain region of the first field effect transistor and the fourth source/drain region of the second field effect transistor; and an isolation layer sandwiched between the first stack of nanosheets and the second stack of nanosheets and between the metalized, fully embedded contact and the first interlayer dielectric. The first field effect transistor is a first polarity and the second field effect transistor is a second polarity different than the first polarity.

According to another aspect, an exemplary method for making a semiconductor structure includes forming, on a substrate, a first field effect transistor, a second field effect transistor, and an isolation layer between the first field effect transistor and the second field effect transistor, in which the first field effect transistor includes a first source/drain region, a second source/drain region, a first stack of nanosheets between the first source/drain region and the second source/drain region, and a metal gate surrounding the first stack of nanosheets; and the second field effect transistor includes a third source/drain region, a fourth source/drain region, a second stack of nanosheets between the third source/drain region and the fourth source/drain region, and the metal gate surrounding the second stack of nanosheets. The method further includes depositing a spacer, the spacer surrounding the metal gate and covering a top surface of the first source/drain region and the second source/drain region, sidewalls of the isolation layer, and a surrounding of the third source/drain region and the fourth source/drain region; depositing a first interlayer dielectric to fill a gap between the first source/drain region and the third source/drain region, a second gap between the second source/drain region and the fourth source/drain region, and an area above the third source/drain region and the fourth source/drain region; removing, using a mask, the first interlayer dielectric and the spacers from the gap between the first source/drain region and the third source/drain region and surrounding the third source/drain region; depositing a metalized material; and selectively removing, using the mask and the third source/drain region, the metalized material, leaving a portion of the metalized material to form a metalized embedded contact between the first source/drain region and the third source/drain region.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1A illustrates a top-down view of a semiconductor structure after a processing operation according to one or more exemplary embodiments of the invention;

FIGS. 1B and 1C illustrate cross-sectional views of the semiconductor structure shown in FIG. 1A taken along the lines X-X′ and Y1-Y1′, respectively, after a processing operation, according to one or more exemplary embodiments of the invention;

FIG. 2 illustrates a cross-sectional view of the semiconductor structure shown in FIG. 1A taken along the line X-X′ after a processing operation, according to one or more exemplary embodiments of the invention;

FIGS. 3A and 3B illustrate cross-sectional views of the semiconductor structure shown in FIG. 1A taken along the lines X-X′ and Y1-Y1′, respectively, after a processing operation, according to one or more exemplary embodiments of the invention;

FIGS. 4A and 4B illustrate cross-sectional views of the semiconductor structure shown in FIG. 1A taken along the lines X-X′ and Y1-Y1′, respectively, after a processing operation, according to one or more exemplary embodiments of the invention;

FIGS. 5A and 5B illustrate cross-sectional views of the semiconductor structure shown in FIG. 1A taken along the lines X-X′ and Y1-Y1′, respectively, after a processing operation, according to one or more exemplary embodiments of the invention;

FIGS. 6A and 6B illustrate cross-sectional views of the semiconductor structure shown in FIG. 1A taken along the lines X-X′ and Y1-Y1′, respectively, after a processing operation, according to one or more exemplary embodiments of the invention;

FIGS. 7A and 7B illustrate cross-sectional views of the semiconductor structure shown in FIG. 1A taken along the lines X-X′ and Y1-Y1′, respectively, after a processing operation, according to one or more exemplary embodiments of the invention;

FIGS. 8A and 8B illustrate cross-sectional views of the semiconductor structure shown in FIG. 1A taken along the lines X-X′ and Y1-Y1′, respectively, after a processing operation, according to one or more exemplary embodiments of the invention;

FIGS. 9A and 9B illustrate cross-sectional views of the semiconductor structure shown in FIG. 1A taken along the lines X-X′ and Y1-Y1′, respectively, after a processing operation, according to one or more exemplary embodiments of the invention;

FIG. 10 illustrates a cross-sectional view of the semiconductor structure shown in FIG. 1A taken along the line X-X′ after a processing operation, according to one or more exemplary embodiments of the invention;

FIG. 11 illustrates a cross-sectional view of the semiconductor structure shown in FIG. 1A taken along the line X-X′ after a processing operation, according to one or more exemplary embodiments of the invention;

FIGS. 12A-12C illustrate cross-sectional views of the semiconductor structure shown in FIG. 1A taken along the lines X-X′, Y1-Y1′, and Y2-Y2′, respectively, after a processing operation, according to one or more exemplary embodiments of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary semiconductor structure 3000 includes a substrate 1001; a first field effect transistor 1003 located on the substrate 1001, the first field effect transistor 1003 having a first stack of nanosheets 1005, a metal gate 1009, a first source/drain region 1015, and a second source/drain region 1017; a second field effect transistor 1025 located on the first field effect transistor 1003, the second field effect transistor 1025 having a second stack of nanosheets 1027, the metal gate 1009, a third source/drain region 1029, and a fourth source/drain region 1031; and a metalized embedded contact 5033 sandwiched between the first source/drain region 1015 of the first field effect transistor 1003 and the third source/drain region 1029 of the second field effect transistor 1025, the metalized embedded contact 5033 filling a gap 4045 between the first source/drain region 1015 and the third source/drain region 1029. Technical benefits include a reduction in materials used, parasitic capacitance, and contact resistance, and an increase in cell height scaling, over previous approaches. The metalized embedded contact 5033 can directly connect, both physically and electrically, the first source/drain region 1015 of the first field effect transistor 1003 to the third source/drain region 1029 of the second field effect transistor 1025, minimizing a use of vias and electrical connections to levels outside of (i.e., above or below) the stacked field effect transistor semiconductor structure 3000.

Optionally, the metalized embedded contact 5033 can directly contact, without any intervening layers, the first source/drain region 1015 of the first field effect transistor 1003 and the third source/drain region 1029 of the second field effect transistor 1025 and electrically connect the first source/drain region 1015 of the first field effect transistor 1003 to the third source/drain region 1029 of the second field effect transistor 1025. Technical benefits include a reduction in parasitic capacitance and contact resistance, as the metalized embedded contact 5033 can directly connect, both physically and electrically, the first source/drain region 1015 of the first field effect transistor 1003 to the third source/drain region 1029 of the second field effect transistor 1025, reducing the distance and amount of metal between the first source/drain region 1015 and the third source/drain region 1029, over previous approaches.

In further options, the first source/drain region 1015 of the first field effect transistor 1003 can be a first drain, the second source/drain region 1017 of the first field effect transistor 1003 can be a first source, the third source/drain region 1029 of the second field effect transistor 1025 can be a second drain, and the fourth source/drain region 1031 of the second field effect transistor 1025 can be a second source. In other options, the first source/drain region 1015 of the first field effect transistor 1003 can be a first drain, the second source/drain region 1017 of the first field effect transistor 1003 can be a first source, the third source/drain region 1029 of the second field effect transistor 1025 can be a second source, and the fourth source/drain region 1031 of the second field effect transistor 1025 can be a second drain. In still other options, the first source/drain region 1015 of the first field effect transistor 1003 can be a first source, the second source/drain region 1017 of the first field effect transistor 1003 can be a first drain, the third source/drain region 1029 of the second field effect transistor 1025 can be a second source, and the fourth source/drain region 1031 of the second field effect transistor 1025 can be a second drain. Technical benefits include a metalized embedded contact 5033 that can be used to directly connect either a source or a drain of the first field effect transistor 1003 to either a source or a drain of the second field effect transistor 1025, minimizing a use of vias and/or electrical connections to levels outside of (i.e., above or below) the stacked field effect transistor semiconductor structure 3000 in a variety of applications, such as source-to-drain connections, source-to-source connections, and/or drain-to-drain connections, thus, reducing materials used, parasitic capacitance, and contact resistance, and increasing cell height scaling, over previous approaches.

Continuing with options, the first field effect transistor 1003 can be a first polarity and the second field effect transistor 1025 can be a second polarity different than the first polarity. Technical benefits include use in complementary metal-oxide semiconductors used to implement logic functions.

Further, optionally, the first source/drain region 1015 can have a length L1 greater than the third source/drain region 1029 and the metalized embedded contact 5033 can have a same width W and length L2 as the third source/drain region 1029. Technical benefits include a metalized embedded contact 5033 with a greater contact area (e.g., as opposed to smaller via connections used in previous approaches) between the metalized embedded contact 5033 and the first source/drain region 1015 and the third source/drain region 1029, resulting in a reduction in parasitic capacitance and contact resistance.

In further options, the semiconductor structure 3000 can include an isolation layer 1019 sandwiched between the first field effect transistor 1003 and the second field effect transistor 1025. In some options, the metalized embedded contact 5033 can be adjacent to and contacting a first sidewall 1021 of the isolation layer 1019. Technical benefits include an electrical isolation between the first stack of nanosheets 1005 of the first field effect transistor 1003, the second stack of nanosheets 1027 of the second field effect transistor 1025, and the metalized embedded contact 5033.

In still further options, the semiconductor structure 3000 can include a first interlayer dielectric 1039 located adjacent to a second sidewall 1023 of the isolation layer 1019 and between the second source/drain region 1017 of the first field effect transistor 1003 and the fourth source/drain region 1031 of the second field effect transistor 1025, in which the second sidewall 1023 of the isolation layer 1019 can be opposite the first sidewall 1021 of the isolation layer 1019. Optionally, the semiconductor structure 3000 can include a spacer 1013a, in which the spacer 1013a can separate the first interlayer dielectric 1039 from the second sidewall 1023 of the isolation layer 1019, the second source/drain region 1017 of the first field effect transistor 1003, and the fourth source/drain region 1031 of the second field effect transistor 1025 and the first interlayer dielectric 1039 can fill an area between the second source/drain region 1017 of the first field effect transistor 1003 and the fourth source/drain region 1031 of the second field effect transistor 1025. Technical benefits include separation of the second source/drain region 1017 of the first field effect transistor 1003 from the fourth source/drain region 1031 of the second field effect transistor 1025 and a reduction in parasitic capacitance between conductive structures of the semiconductor structure 3000.

According to another aspect of the invention, an exemplary semiconductor structure 3000 includes a first field effect transistor 1003 including a first source/drain region 1015, a second source/drain region 1017, a first stack of nanosheets 1005 between the first source/drain region 1015 and the second source/drain region 1017, and a metal gate 1009 surrounding the first stack of nanosheets 1005; a second field effect transistor 1025 located on the first field effect transistor 1003, the second field effect transistor 1025 including a third source/drain region 1029, a fourth source/drain region 1031, a second stack of nanosheets 1027 between the third source/drain region 1029 and the fourth source/drain region 1031, and the metal gate 1009 surrounding the second stack of nanosheets 1027; a metalized, fully embedded contact 5033 sandwiched between and directly contacting the first source/drain region 1015 of the first field effect transistor 1003 and the third source/drain region 1029 of the second field effect transistor 1025, the metalized, fully embedded contact 5003 filling a gap 4045 between the first source/drain region 1015 and the third source/drain region 1029; a first interlayer dielectric 1039 located between the second source/drain region 1017 of the first field effect transistor 1003 and the fourth source/drain region 1031 of the second field effect transistor 1025; and an isolation layer 1019 sandwiched between the first stack of nanosheets 1005 and the second stack of nanosheets 1027 and between the metalized, fully embedded contact 5033 and the first interlayer dielectric 1039, in which the first field effect transistor 1003 can be a first polarity and the second field effect transistor 1025 can be a second polarity different than the first polarity. Technical benefits include directly connecting, both physically and electrically, the first source/drain region 1015 of the first field effect transistor 1003 to the third source/drain region 1029 of the second field effect transistor 1025, through the metalized embedded contact 5033. The metalized embedded contact 5033 can minimize a use of vias and electrical connections to levels outside of (i.e., above or below) the stacked field effect transistor semiconductor structure 3000, resulting in a reduction in materials used, parasitic capacitance and contact resistance between the first source/drain region 1015 and the third source/drain region 1029, and an increase in cell height scaling, over previous approaches. Technical benefits further include the isolation layer 1019 electrically isolating the first stack of nanosheets 1005, the second stack of nanosheets 1027, and the metalized embedded contact 5033 from each other. Further, technical benefits include different polarities in field effect transistors, thus utilizing the metalized embedded contact 5033 in complementary metal-oxide semiconductors used to implement logic functions.

Optionally, the first source/drain region 1015 of the first field effect transistor 1003 can be a drain of the first field effect transistor 1003, the third source/drain region 1029 of the second field effect transistor 1025 can be a drain of the second field effect transistor 1025, and the metalized, fully embedded contact 5033 can be sandwiched between and electrically connect the drain of the first field effect transistor 1003 and the drain of the second field effect transistor 1025. Technical benefits include a metalized embedded contact 5033 that can be used to directly connect a drain of the first field effect transistor 1003 to a drain of the second field effect transistor 1025, minimizing a use of vias and/or electrical connections to levels outside of (i.e., above or below) the stacked field effect transistor semiconductor structure 3000 in drain-to-drain connection applications, thus, reducing materials used, parasitic capacitance, and contact resistance, and increasing cell height scaling, over previous approaches.

In other options, the first source/drain region 1015 can be one of a source and a drain of the first field effect transistor 1003 and the third source/drain region 1029 can be another of a source and a drain of the second field effect transistor 1025 and the metalized, fully embedded contact 5033 can be sandwiched between and electrically connecting one of the source of the first field effect transistor 1003 and the drain of the second field effect transistor 1025 and the drain of the first field effect transistor 1003 and the source of the second field effect transistor 1025. Technical benefits include a metalized embedded contact 5033 that can be used to directly connect either a source of the first field effect transistor 1003 to a drain of the second field effect transistor 1025 or a drain of the first field effect transistor 1003 to a source of the second field effect transistor 1025, minimizing a use of vias and/or electrical connections to levels outside of (i.e., above or below) the stacked field effect transistor semiconductor structure 3000 in source-to-drain connection applications, thus, reducing materials used, parasitic capacitance, and contact resistance, and increasing cell height scaling, over previous approaches.

In further options, the first source/drain region 1015 of the first field effect transistor 1003 can be a source of the first field effect transistor 1003, the third source/drain region 1029 of the second field effect transistor 1025 can be a source of the second field effect transistor 1025, and the metalized, fully embedded contact 5033 can be sandwiched between and electrically connecting the source of the first field effect transistor 1003 and the source of the second field effect transistor 1025. Technical benefits include a metalized embedded contact 5033 that can be used to directly connect a source of the first field effect transistor 1003 to a source of the second field effect transistor 1025, minimizing a use of vias and/or electrical connections to levels outside of (i.e., above or below) the stacked field effect transistor semiconductor structure 3000 in source-to-source connections applications, thus, reducing materials used, parasitic capacitance, and contact resistance, and increasing cell height scaling, over previous approaches.

An aspect of an exemplary method of making a semiconductor structure 3000 includes forming, on a substrate 1001, a first field effect transistor 1003, a second field effect transistor 1025, and an isolation layer 1019 between the first field effect transistor 1003 and the second field effect transistor 1025, in which the first field effect transistor 1003 includes a first source/drain region 1015, a second source/drain region 1017, a first stack of nanosheets 1005 between the first source/drain region 1015 and the second source/drain region 1017, and a metal gate 1009 surrounding the first stack of nanosheets 1005 and the second field effect transistor 1025 includes a third source/drain region 1029, a fourth source/drain region 1031, a second stack of nanosheets 1027 between the third source/drain region 1029 and the fourth source/drain region 1031, and the metal gate 1009 surrounding the second stack of nanosheets 1027; depositing a spacer 1013a, the spacer 1013a surrounding the metal gate 1009 and covering a top surface of the first source/drain region 1015 and the second source/drain region 1017, sidewalls 1021, 1023 of the isolation layer 1019, and a surrounding of the third source/drain region 1029 and the fourth source/drain region 1031; depositing a first interlayer dielectric 1039 to fill a gap between the first source/drain region 1015 and the third source/drain region 1029, a second gap between the second source/drain region 1017 and the fourth source/drain region 1031, and an area above the third source/drain region 1029 and the fourth source/drain region 1031; removing, using a mask 2043, the first interlayer dielectric 1039 and the spacers 1013a from the gap 4045 between the first source/drain region 1015 and the third source/drain region 1029 and surrounding the third source/drain region 1029; depositing a metalized material; and selectively removing, using the mask 2043 and the third source/drain region 1029, the metalized material, leaving a portion of the metalized material to form a metalized embedded contact 5033 between the first source/drain region 1015 and the third source/drain region 1029. Technical benefits include forming an asymmetrical source/drain metalized connection between the first field effect transistor 1003 and the second field effect transistor 1025 by forming a direct connection, both physically and electrically, between the first source/drain region 1015 of the first field effect transistor 1003 and the third source/drain region 1029 of the second field effect transistor 1025, through the metalized embedded contact 5033. The metalized embedded contact 5033 can electrically connect the first source/drain region 1015 to the third region source/drain 1029 without a use of vias and/or electrical connections to levels outside of (i.e., above or below) the stacked field effect transistor semiconductor structure 3000, resulting in a reduction in materials used, a reduction in parasitic capacitance and contact resistance between the first source/drain region 1015 and the third source/drain region 1029, and an increase in cell height scaling, over previous approaches. Technical benefits further include the isolation layer 1019 electrically isolating the first stack of nanosheets 1005 from the second stack of nanosheets 1027.

Optionally, after the first interlayer dielectric 1039 and the spacer 1013a is removed from the gap 4045 between the first source/drain region 1015 and the third source/drain region 1029, the gap 4045 can be filled with the metalized embedded contact 5033, in which the metalized embedded contact 5033, without etching the first source/drain region 1015 nor the third source/drain region 1029, directly connects, physically and electrically, the first source/drain region 1015 and the third source/drain region 1029 and the second gap between the second source/drain region 1017 and the fourth source/drain region 1031 can be lined with the spacer 1013a and filled with the first interlayer dielectric 1039. Technical benefits include the metalized embedded contact 5033 directly connecting, both physically and electrically, the first source/drain region 1015 of the first field effect transistor 1003 to the third source/drain region 1029 of the second field effect transistor 1025, reducing a distance and amount of metal used between the first source/drain region 1015 and the third source/drain region 1029, resulting in a reduction in parasitic capacitance and contact resistance, over previous approaches.

In further options, the method of making the semiconductor structure 3000 can further include depositing a second spacer 1013c on the top surface of the third source/drain region 1029, a portion of the metal gate 1009 located above the second stack of nanosheets 1027, and the mask 2043. Technical benefits include separation of the third source/drain region 1029 from a second interlayer dielectric 8041 deposited on the second spacer 1013c and a reduction in parasitic capacitance between structures of the semiconductor structure 3000.

In still further options, the method of making the semiconductor structure 3000 can include depositing and etching a second interlayer dielectric 8041 to fill the area above the third source/drain region 1029. Further, optionally, the second interlayer dielectric 8041 can be a low-k dielectric. Technical benefits of a low-k dielectric include a reduction in parasitic capacitance between conductive structures and a potential for improvement in cell height scaling.

In some options, the method of making the semiconductor structure 3000 can include removing the second spacer 1013c from the mask 2043 and removing the mask 2043. Technical benefits include a completed semiconductor structure 3000 that includes a direct connection (i.e., the metalized embedded contact 5033) between the first source/drain 1015 region of the first field effect transistor 1003 and the third source/drain region 1029 of the second field effect transistor 1025 without a use of vias and/or electrical connections to levels outside of (i.e., above or below) the stacked field effect transistor semiconductor structure 3000, resulting in a reduction in materials used, a reduction in parasitic capacitance and contact resistance between the first source/drain region 1015 and the third source/drain region 1029, and an increase in cell height scaling, over previous approaches.

Techniques as disclosed herein can provide substantial beneficial technical effects. Some embodiments may not have these potential advantages, and these potential advantages are not necessarily required of all embodiments. By way of example only and without limitation, one or more embodiments can provide a performance boost by reduction in parasitic capacitance, an improvement in block level performance by reduction in Cell-to-Cell parasitic between logic designs, an increase in cell height scaling, and a reduction in contact resistance, in a stacked field effect transistor (e.g., monolithic, sequential, etc.):
by creating a reduced tall drain to gate metal area cap;
by utilizing a low-k dielectric fill;
by directly connecting, using a metallized embedded contact, a drain/source region of a first field effect transistor to a drain/source region of a second field effect transistor;
by forming an asymmetrical source/drain metallized connection between a bottom nanosheet stacked field effect transistor and a top nanosheet stacked field effect transistor;
by etching an area between source/drain regions of vertically stacked field effect transistors) to create a gap, and filling the gap with a metalized material to create a contact between the source/drain regions;
by, prior to an MOL (middle-of-line) step, forming a fully embedded source/drain metalized contact of a vertically stacked n-type field effect transistor and p-type field effect transistor.

It is understood in advance that although the following example embodiments are described in connection with a particular vertically stacked nanosheet complementary metal-oxide semiconductor transistor architecture, embodiments are not limited to the particular transistor architectures or materials described within this specification. Rather, embodiments herein are capable of being implemented in conjunction with any other type of transistor architecture or materials now known or later developed.

For the sake of brevity, conventional techniques related to semiconductor device and integrated circuit fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details. Given the teachings herein, the skilled artisan can readily make and use embodiments of the invention.

Turning now to exemplary embodiments, a metal-oxide-semiconductor field-effect transistor can be used, for example, for amplifying or switching electronic signals. N-type field effect transistors and P-type field effect transistors are two types of complementary metal-oxide-semiconductor field-effect transistors. Complementary metal-oxide semiconductor is a technology that uses complementary and symmetrical pairs of P-type and N-type metal-oxide-semiconductor field-effect transistors to implement logic functions.

The wafer footprint of a field effect transistor is related to the electrical conductivity of the channel material. If the channel material has a relatively high conductivity, the field effect transistor can be made with a corresponding smaller wafer footprint. A known method of increasing channel conductivity and decreasing field effect transistor size is to form the channel as a nanostructure. For example, a so-called gate-all-around nanosheet field effect transistor is a known architecture for providing a relatively small field effect transistor footprint by forming the channel region as a series of nanosheets. In a known gate-all-around configuration, a nanosheet-based field effect transistor includes a source region, a drain region, and stacked nanosheet channels between the source and drain regions. A gate surrounds the stacked nanosheet channels and regulates electron flow through the nanosheet channels between the source and drain regions. Gate-all-around nanosheet field effect transistors are fabricated by forming alternating layers of channel nanosheets (e.g., Si) and sacrificial nanosheets (e.g., SiGe). The sacrificial nanosheets are released from the channel nanosheets before the field effect transistor device is finalized. Forming the gate-all-around nanosheets from alternating layers of channel nanosheets, formed from a first type of semiconductor material, and sacrificial nanosheets, formed from a second type of semiconductor material, can provide for channel electrostatic control.

Source/drain regions of field effect transistors) in a stacked nanosheet field effect transistor architecture can be electrically connected. In some previous approaches, a source/drain region in a first field effect transistor can be connected to circuitry external (e.g., a wiring level or layer above or below the stacked field effect transistor structure) to the stacked nanosheet field effect transistor architecture and a source/drain region in a second field effect transistor can be connected to the same circuitry, thus electrically connecting a source/drain region of the first field effect transistor to a source/drain region of the second field effect transistor. Further, one or more source/drain regions of field effect transistors) in the stacked nanosheet field effect transistor architecture can be electrically connected (e.g., through interconnects such as vias), to power, ground, and/or other signal lines within one or more wiring layers above or below the stacked field effect transistor structure.

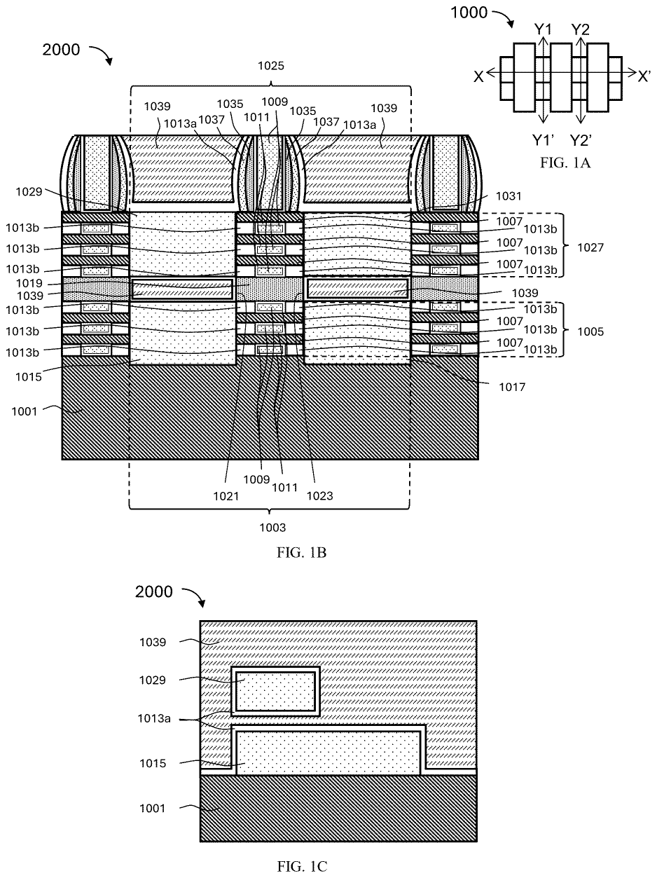

Turning now to a more detailed description of fabrication operations and resulting structures, a top-down reference view 1000, shown in FIG. 1A, provides a reference point for the various cross-sectional views: line X-X′ view, line Y1-Y1′ view, and line Y2-Y2′ view shown, at least in part, in FIGS. 1B-12C. FIG. 1A illustrates a top-down view 1000 of a semiconductor structure during an intermediate operation of a method of fabricating a semiconductor device according to one or more embodiments of the invention. FIGS. 1B-12C illustrate a semiconductor structure after various fabrication operations in accordance with aspects of the following exemplary embodiments. Although the cross-sectional diagrams illustrated in FIGS. 1B-12C are two-dimensional, it is understood that the diagrams illustrated in FIGS. 1B-12C represent three-dimensional structures.

FIG. 1B illustrates a cross-sectional view 1000 of the semiconductor structure, as shown in FIG. 1A, taken along the line X-X′ while FIG. 1C illustrates a cross-sectional view 1000 of the semiconductor structure, as shown in FIG. 1A, taken along the line Y1-Y1′.

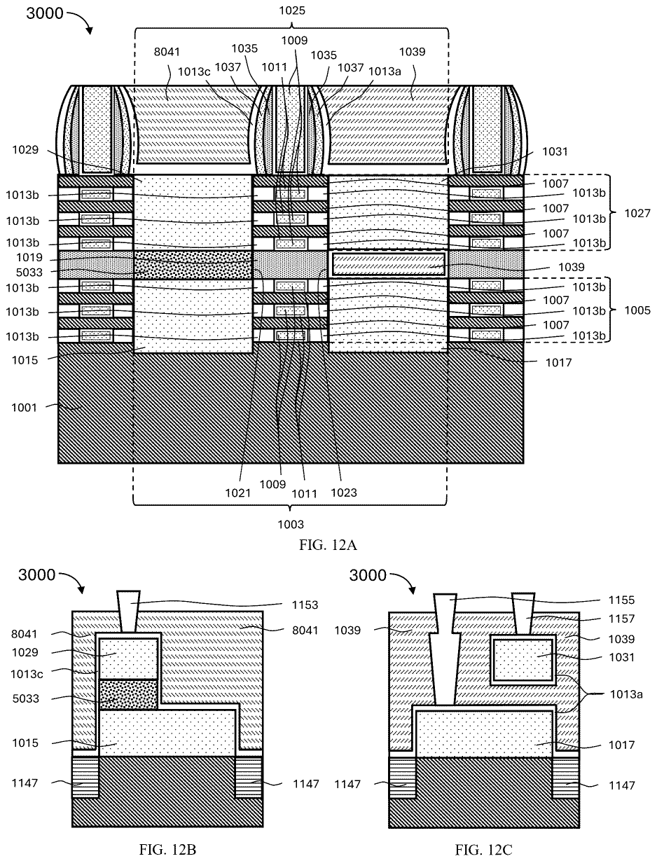

As illustrated in FIG. 1B, a semiconductor structure 2000 of a partially fabricated semiconductor device can include a substrate 1001, made of any suitable substrate material. For example, the substrate 1001 can include monocrystalline silicon (Si), silicon germanium (SiGe), III-V compound semiconductor, II-VI compound semiconductor, or semiconductor-on-insulator. In some embodiments, the substrate 1001 can be a silicon substrate. In some embodiments, the substrate 1001 can include a buried oxide layer (not shown), made of any suitable material, such as silicon oxide, though examples are not so limiting. Further, in some embodiments, the semiconductor structure 2000 can be electrically isolated from other regions of the substrate 1001 by a shallow trench isolation region (e.g., STI 1147 as illustrated in FIGS. 12B-12C).

The semiconductor structure 2000 can include a first field effect transistor 1003 including a first stack of nanosheets 1005 and a second field effect transistor 1025 including a second stack of nanosheets 1027. The second stack of nanosheets 1027 can be, as will be described in further detail herein, formed over the first stack of nanosheets 1005. The first stack of nanosheets 1005 and the second stack of nanosheets 1027 can include nanosheets (i.e., semiconductor layers) 1007. In some embodiments, each nanosheet 1007 can be surrounded by a gate dielectric 1011 and a metal gate 1009. The metal gate 1009 can extend through the second stack of nanosheets 1027 and the first stack of nanosheets 1005 and to the substrate 1001. Further, the first stack of nanosheets 1005 and the second stack of nanosheets 1027 can be separated by an isolation layer 1019, though examples are not so limiting.

For example, the first stack of nanosheets 1005 of one or more semiconductor layers 1007 alternating with one or more sacrificial layers (not shown) can be formed over the substrate 1001. In some embodiments, the first stack of nanosheets 1005 can be formed such that a topmost and a bottommost layer of the first stack of nanosheets 1005 are sacrificial layers. Note, while FIGS. 1B-12C illustrate the first stack of nanosheets 1005 having two semiconductor layers 1007, it is to be understood that the first stack of nanosheets 1005 can include any number of semiconductors layers 1007.

The semiconductor layers 1007 can be made of any suitable semiconductor channel material, such as monocrystalline Si, III-V compound semiconductor, II-VI compound semiconductor, or the like. In some embodiments, the semiconductor layers 1007 can be made of silicon. Further, the sacrificial layers (not shown) can be made of any suitable material, such as SiGe.

The semiconductor layers 1007 and the sacrificial layers can be formed by a variety of methods, such as ultrahigh vacuum chemical vapor deposition (UHVCVD), rapid thermal chemical vapor deposition (RTCVD), metalorganic chemical vapor deposition (MOCVD), low pressure chemical vapor deposition (LPCVD), limited response processes chemical vapor deposition (LRPCVD), molecular beam epitaxy (MBE), and the like. In some embodiments, the semiconductor layers 1007 and the sacrificial layers can be epitaxially grown from gaseous or liquid precursors, though examples are not so limiting. Epitaxial semiconductor materials can be grown using vapor-phase epitaxy (VPE), MBE, liquid-phase epitaxy (LPE), or other suitable processes.

The isolation layer 1019 can be formed over the first stack of nanosheets 1005. In some examples, the isolation layer 1019 can be a rare earth oxide (REO) made of any suitable rare earth oxide material, such as yttrium oxide (Y₂O₃), lanthanum oxide (La₂O₃), cerium oxide (CeO₂), praseodymium oxide (Pr₆O₁₁), neodymium oxide (Nd₂O₃), and the like, and can be epitaxially grown on a surface of the first stack of nanosheets 1005. In some embodiments, the isolation layer 1019 can be made of a dielectric material, such as an oxide, and can be formed by directional high-density plasma (HDP) oxide deposition or other applicable processes, though examples are not so limiting. In still further embodiments, the isolation layer 1019 can include silicon boron carbon nitride (SiBCN).

The second stack of nanosheets 1027, including one or more semiconductor layers 1007 alternating with one or more sacrificial layers (not shown), can be formed over the isolation layer 1019. Note, while FIGS. 1B-12C illustrate the second stack of nanosheets 1027 having three semiconductor layers 1007, it is to be understood that the second stack of nanosheets 1027 can include any number of semiconductors layers 1007. In some embodiments, the semiconductor layers 1007 can be made of silicon and the sacrificial layers can be made of SiGe and can be formed utilizing the same processes as described in reference to the first stack of nanosheets 1005.

A hard mask (not shown) can be formed on a topmost surface of the second stack of nanosheets 1027. In some embodiments, the hard mask can include a nitride, such as silicon nitride, and/or an oxide, such as silicon dioxide (SiO₂), though examples are not so limiting. Portions of the hard mask can then be removed (e.g., patterned) to expose one or more surfaces of the second stack of nanosheets 1027. In some embodiments, the first stack of nanosheets 1005, the second stack of nanosheets 1027, and the isolation layer 1019 can be patterned selective to the hard mask. Portions of the first stack of nanosheets 1005, the second stack of nanosheets 1027, and the isolation layer 1019 can be removed using a wet etch, a dry etch, or a combination of sequential wet and/or dry etches. In this manner, the first stack of nanosheets 1005 and the second stack of nanosheets 1027 can be patterned. In some embodiments, the patterning process removes a portion of a topmost surface of the substrate 1001, though examples are not so limiting. After this, the hard mask can be removed.

A sacrificial gate (also known as a dummy gate) can be formed over a surface of the second stack of nanosheets 1027. The sacrificial gate can be made of any suitable material, such as amorphous silicon or poly-silicon and can be formed using known methods for patterning a sacrificial gate, such as a polysilicon fill and wet etch, a dry etch, or a combination of sequential wet and/or dry etches. A second hard mask made of any suitable material, such as silicon nitride and/or silicon oxide, can be formed on the sacrificial gate. In some embodiments, the sacrificial gate can be formed by patterning the second hard mask, and, utilizing known processes such as reactive ion etch (RIE), removing portions of the sacrificial gate not covered by the second hard mask.

In some embodiments, spacers 1013a can be formed on sidewalls of the sacrificial gate. In some embodiments, the spacers 1013a can be formed using processes such as chemical vapor deposition (CVD), plasma enhanced CVD (PECVD), atomic layer deposition (ALD), physical vapor deposition (PVD), chemical solution deposition, or other like processes in combination with a wet or dry etch process. As one non-limiting example, spacer material can be conformally deposited over the semiconductor structure 2000 and selectively removed using a reactive ion etch (RIE) to form the spacers 1013a. The spacers 1013a can be made of any suitable material, such as a low-k dielectric. For example, the spacers 1013a can be made of nitride, silicon nitride (such as Si₃N₄), silicon oxide (such as SiO₂), SiON, SiC, SiOCN, or SiBCN, though examples are not so limiting. In some non-limiting embodiments, and as shown in FIG. 1B, spacers 1013a formed on the sacrificial gate can further include a first layer 1035, such as a layer of SiBCN; a second layer 1037, such as a layer of SiO₂; and a third layer 1013a, such as a layer of Si₃N₄, though examples of embodiments are not so limiting.

Portions of the first stack of nanosheets 1005, the second stack of nanosheets 1027, and the isolation layer 1019 can be removed to expose a surface of the substrate 1001. A portion of a topmost surface of the substrate 1001, in some embodiments, can also be removed, though examples are not so limiting. In some embodiments, portions of the first stack of nanosheets 1005, the second stack of nanosheets 1027, and the isolation layer 1019 can be removed using an anisotropic etch such as a RIE process. In this manner, the first stack of nanosheets 1005 and the second stack of nanosheets 1027 can be patterned to form source and drain recesses. In some embodiments, sidewalls of the sacrificial layers can be recessed selective to the semiconductor layers 1007 to form one or more recesses. That is, in some embodiments, portions of the sacrificial layers can be removed using a SiGe etch selective to silicon. An example SiGe etch process selective to silicon is a selective HCl gas etch.

Spacer material, forming spacers 1013b, can be deposited or otherwise formed in each recess. In some embodiments, the spacers 1013b can be formed by a conformal deposition (e.g., CVD or ALD) to plug the recesses followed by an etch back process to remove any excessive material. The spacers 1013b can be made of any suitable material, such as a low-k dielectric material. For example, as previously described in references to spacers 1013a, the spacers 1013b can be made of nitride, silicon nitride, silicon oxide, SiON, SiC, SiOCN, or SiBCN.

In some embodiments, source and drain regions can be formed over the substrate 1001, creating a first epitaxial layer 1015 on a first side of the first stack of nanosheets 1005 and a second epitaxial layer 1017 on a second side of the first stack of nanosheets 1005. The first epitaxial layer 1015 and the second epitaxial layer 1017 (i.e., source and drain regions of the first stack of nanosheets 1005) can be formed in the source and drain recesses, on opposite sides of the first stack of nanosheets 1005. The first epitaxial layer 1015 and the second epitaxial layer 1017 can be epitaxially formed by a variety of methods, such as in situ doped epitaxy, doped following the epitaxy, or by implantation and plasma doping. In some embodiments, epitaxial regions are epitaxially grown over the substrate 1001. The first epitaxial layer 1015 and the second epitaxial layer 1017 can, in some embodiments, be epitaxial semiconductor materials grown from gaseous liquid precursors, though examples are not so limiting. The first epitaxial layer 1015 and the second epitaxial layer 1017 can be doped with either n-type dopants (e.g., phosphorus or arsenic) or p-type dopants (e.g., boron or gallium). In some embodiments, the first epitaxial layer 1015 and the second epitaxial layer 1017 are Si:P (phosphorus doped silicon) regions. A surface of the first epitaxial layer 1015 and the second epitaxial layer 1017 can be recessed below a top surface of the isolation layer 1019, confining the first epitaxial layer 1015 and the second epitaxial layer 1017 to the first stack of nanosheets 1005.

As shown in FIGS. 1B and 1C, spacer material, forming the spacers 1013a over the first epitaxial layer 1015 and the second epitaxial layer 1017 and on a first sidewall 1021 and a second sidewall 1023 of the isolation layer 1019, can be deposited and selectively removed using processes and/or materials as previously described. A first interlayer dielectric 1039 can be deposited over the surface of the spacers 1013a and adjacent to the first sidewall 1021 and the second sidewall 1023 of the isolation layer 1019. The first interlayer dielectric 1039 can be made of any suitable material, such as a porous silicate, carbon doped oxide, silicon dioxide, silicon oxynitride, or any suitable low-k dielectric material, and can be deposited using processes known in the art, such as a flowable chemical vapor deposition (FCVD), CVD, PECVD, ALD, spin-on dielectrics, or PVD, though embodiments are not so limiting. The first interlayer dielectric 1039 can be recessed below a top surface of the first layer of the second stack of nanosheets 1027, forming source and drain recesses for the second field effect transistor 1025. In some embodiments, spacers 1013a can be formed over the recessed first interlayer dielectric 1039.

In some embodiments, source and drain regions can be formed over the first epitaxial layer 1015, second epitaxial layer 1017, and first interlayer dielectric 1039, creating a third epitaxial layer 1029 on a first side of the second stack of nanosheets 1027 and a fourth epitaxial layer 1031 on a second side of the second stack of nanosheets 1027. The third epitaxial layer 1029 and the fourth epitaxial layer 1031 (i.e., source and drain regions of the second stack of nanosheets 1027) can be formed in the source and drain recesses of the second field effect transistor 1025 on opposite sides of the second stack of nanosheets 1027. In some embodiments, the third epitaxial layer 1029 and the fourth epitaxial layer 1031 of the second field effect transistor 1025 can be formed over the first epitaxial layer 1015 and the second epitaxial layer 1017 of the second field effect transistor 1025, respectively.

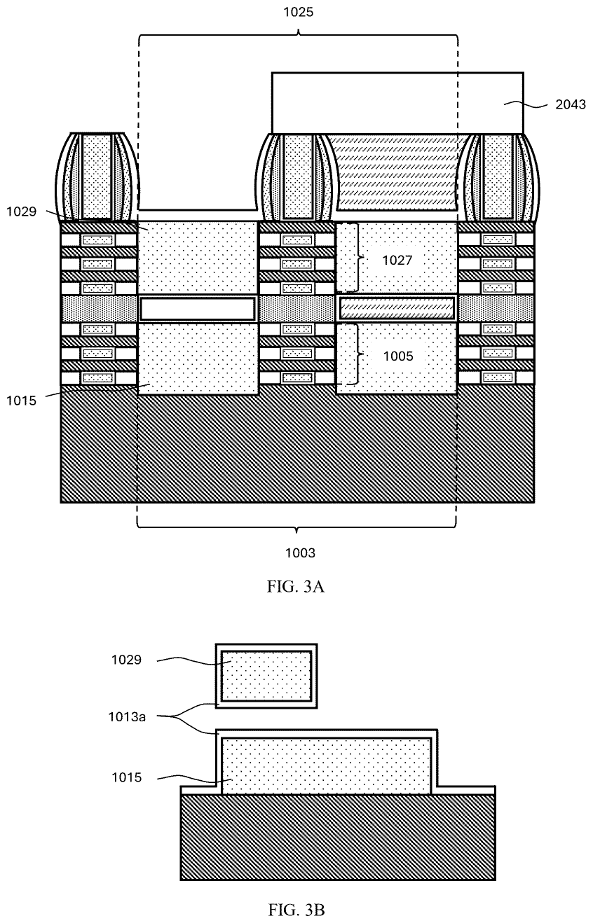

The third epitaxial layer 1029 and the fourth epitaxial layer 1031 can be epitaxially formed utilizing methods such as those previously described in reference to formation of the first epitaxial layer 1015 and the second epitaxial layer 1017. In some embodiments, a length of the third epitaxial layer 1029 and a length of the fourth epitaxial layer 1031 can be similar to a length of the first epitaxial layer 1015 and a length of the second epitaxial layer 1017, respectively (not shown in the FIGS. for brevity). In still other embodiments, as illustrated in FIG. 1C (and in FIGS. 3B, 4B, 5B, 6B, 7B, 8B, 9B, and 12B) the length of the third epitaxial layer 1029 can be less than the length of the first epitaxial layer 1015 (and in reference to FIG. 12C, the length of the fourth epitaxial layer 1031 can be less than the length of the second epitaxial layer 1017). Though FIGS. 3B, 4B, 5B, 6B, 7B, 8B, 9B, and 12B illustrate the length of the first epitaxial layer 1015 being greater than the length of the third epitaxial layer 1029 (and FIG. 12C illustrates the length of the third epitaxial layer 1029 being greater than the length of the fourth epitaxial layer 1031), this is a non-limiting example. Thus, it is contemplated that the lengths can be similar and a similar length between the first epitaxial layer 1015 and the third epitaxial layer 1029 (and between the second epitaxial layer 1017 and the fourth epitaxial layer 1031) can be an exemplary embodiment for each step of the method for forming the semiconductor structure, as described in reference to FIGS. 1B-12C.

Further, the third epitaxial layer 1029 and the fourth epitaxial layer 1031 can be doped to have an opposite doping type from the first epitaxial layer 1015 and the second epitaxial layer 1017. In this manner, the first stack of nanosheets 1005 can correspond to either a p-type field effect transistor or an n-type field effect transistor and the second stack of nanosheets 1027 can correspond to the opposite type; i.e., an n-type field effect transistor when the first stack is for a p-type field effect transistor and a p-type field effect transistor when the first stack is for an n-type field effect transistor. A surface of the third epitaxial layer 1029 and the fourth epitaxial layer 1031 can be recessed to a top surface of the second stack of nanosheets 1027.

As shown in FIGS. 1B and 1C, spacer material, forming spacers 1013a over the third epitaxial layer 1029 and the fourth epitaxial layer 1031, can be deposited and selectively removed using processes and/or materials as previously described. The first interlayer dielectric 1039 can be deposited over the semiconductor structure 2000 and recessed to a top surface of the metal gate 1009. In some embodiments, the first interlayer dielectric 1039 can be planarized to the top surface of the metal gate 1009, using, for example, a chemical mechanical planarization (CMP) process, a non-selective RIE process, or a combination of CMP and RIE processes, though embodiments are not so limiting. It is to be noted that the above-described processes and materials for forming the semiconductor structure 2000 are non-limiting examples and other processes and materials can be contemplated.

As previously stated, source/drain regions of field effect transistors in a stacked nanosheet field effect transistor architecture can be electrically connected. Previous approaches typically connect a source/drain region in a first field effect transistor to a source/drain region in a second field effect transistor through individual connections to circuitry external to the stacked nanosheet field effect transistor architecture. For example, in previous approaches source/drain regions of the first field effect transistor and the second field effect transistor can be connected to wiring levels or layers above and/or below the stacked field effect transistors. That is, in previous approaches, a first via can connect the source/drain region of the first field effect transistor to a wiring layer above (or below) the stacked field effect transistors) (e.g., a connection formed during a MOL level process), a second via can connect the source/drain region of the second field effect transistor to the wiring layer above (or below) the stacked field effect transistor (e.g., a connection formed during the MOL level process), and the wiring layer can electrically connect the two source/drain regions. Such connections can create parasitic capacitance and can take up valuable space. Further, in previous approaches, to electrically connect the source/drain region of the first field effect transistor to a wiring layer above the stacked field effect transistor, typically an opening is etched through the source/drain region of the second field effect transistor, insulated, and filled to form a via that runs from the source/drain region of the first field effect transistor, through the source/drain region of the second field effect transistor, to the wiring layer (and vise-versa to connect the source/drain region of the second field effect transistor to a wiring layer below the stacked field effect transistor).

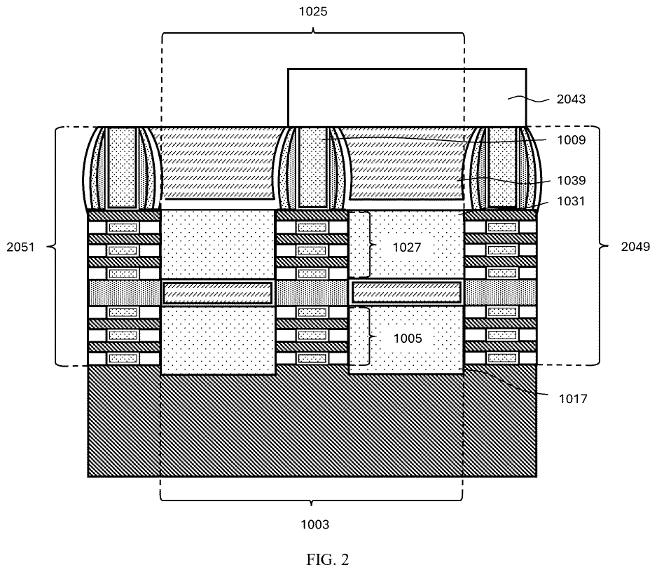

Accordingly, FIGS. 2-12C illustrate an exemplary method of forming a semiconductor structure (e.g., semiconductor structure 3000 as shown in FIGS. 12A-12C) in which a metalized embedded contact 5033 directly connects a source/drain region 1015 of a first field effect transistor 1003 to a source/drain region 1029 of a second field effect transistor 1025. Directly connecting the source/drain region 1015 of the first field effect transistor 1003 to the source/drain region 1029 of the second field effect transistor 1025 can reduce an amount of metal and space utilized in the connection between the source/drain region 1015 of the first field effect transistor 1003 and the source/drain region 1029 of the second field effect transistor 1025, reducing parasitic capacitance and improving cell height scaling over previous approaches. Further, directly connecting the source/drain region 1015 of the first field effect transistor 1003 to the source/drain region 1029 of the second field effect transistor 1025 utilizing the metalized embedded contact 5033 can increase a contact area, reducing a contact resistance within the semiconductor structure.

Accordingly, FIG. 2 illustrates a cross-sectional view 1000 of a semiconductor structure, as shown in FIG. 1A, taken along a line X-X′ during an intermediate operation of a method of fabricating the semiconductor structure. FIG. 2 illustrates the formation of a mask 2043 over a first stack of nanosheets 1005 and second epitaxial layer 1017 of a first field effect transistor 1003, a second stack of nanosheets 1027 and fourth epitaxial layer 1031 of a second field effect transistor 1025, a metal gate 1009 of the first stack of nanosheets 1005 and second stack of nanosheets 1027 of a stacked field effect transistor structure; a first stack and second stack of nanosheets and a gate metal of an adjacent stacked field effect transistor structure 2049; and a first interlayer dielectric 1039 between the two stacked field effect transistor structures. For example, a masking material, such as an organic dielectric layer hard mask (ODL/HM), a soft mask, or any suitable mask known to the skilled artisan, can be formed over the semiconductor structure (e.g., semiconductor structure 2000 as described in reference to FIGS. 1B and 1C) utilizing photolithographic and deposition processes known in the art. Portions of the masking material can be removed or patterned to form the mask 2043. Though FIGS. 2, 3A, 4A, 5A, 6A, 7A, 8A, 9A and 10 illustrate the mask 2043 formed over a particular side (i.e., right side as viewed according to FIGS. 2, 3A, 4A, 5A, 6A, 7A, 8A, 9A and 10) of the first stack of nanosheets 1005 of the first field effect transistor 1003 and the second stack of nanosheets 1027 of the second field effect transistor 1025, embodiments are not so limited and it can be contemplated that the mask 2043 be formed over the opposite side of the first stack of nanosheets 1005 and second stack of nanosheets 1027 and over an opposite adjacent stacked field effect transistor structure 2051.

Continuing to FIGS. 3A and 3B, FIG. 3A illustrates a cross-sectional view 1000 of a semiconductor structure as shown in FIG. 1A, taken along line X-X′, and FIG. 3B illustrates the cross-sectional view 1000 of the semiconductor structure as shown in FIG. 1A, taken along line Y1-Y1′, during an intermediate operation of a method of fabricating the semiconductor structure.

In some embodiments, a portion of a first interlayer dielectric (i.e., first interlayer dielectric 1039 as shown in FIGS. 1B and 1C), that is not covered by a mask 2043, can be removed using processes known in the art, such as a wet or dry etch. In some embodiments, the portion of the first interlayer dielectric can be removed utilizing an oxide etch process, though embodiments are not so limiting. Accordingly, as shown in FIGS. 3A and 3B, the first interlayer dielectric, above a first epitaxial layer 1015 of a first field effect transistor 1003 and surrounding a third epitaxial layer 1029 of a second field effect transistor 1025 stacked on the first field effect transistor 1003, can be selectively removed.

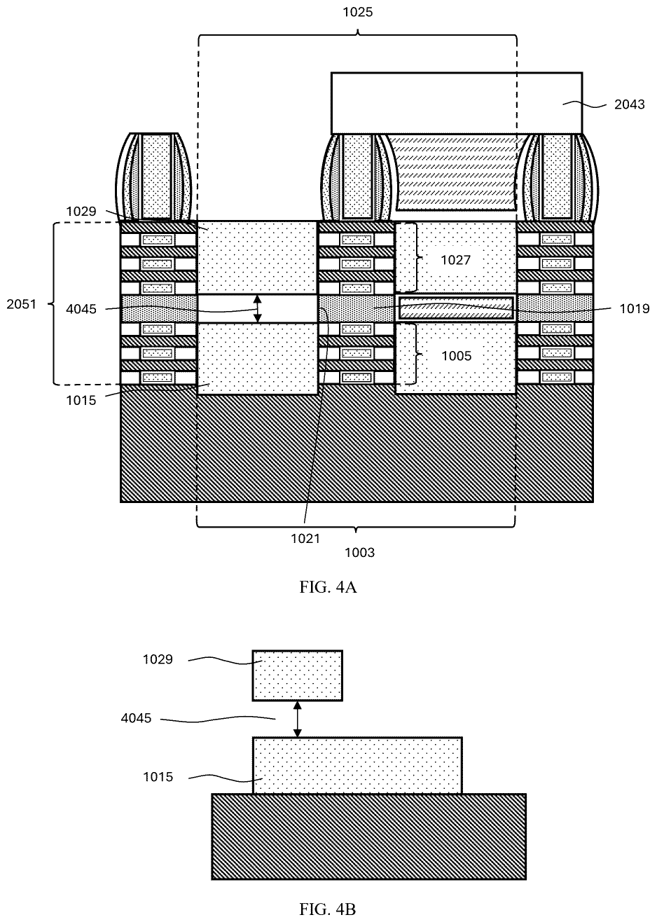

FIGS. 4A and 4B illustrate cross-sectional views 1000 of a semiconductor structure as shown in FIG. 1A taken along lines X-X′ and Y1-Y1′, respectively, during an intermediate operation of a method of fabricating the semiconductor structure. As shown in FIGS. 4A and 4B, spacers (i.e., spacers 1013a as shown in FIGS. 3A and 3B) not covered by a mask 2043, can be removed using processes known in the art, such as a nitride etch as one non-limiting example. Accordingly, as shown in FIGS. 4A and 4B, spacers above a first epitaxial layer 1015 of a first field effect transistor 1003 and surrounding a third epitaxial layer 1029 of a second field effect transistor 1025 stacked on the first field effect transistor 1003 can be selectively removed. Removal of the spacers can leave a gap 4045 between the first epitaxial layer 1015 of the first field effect transistor 1003 and the third epitaxial layer 1029 of the second field effect transistor 1025 and between a first sidewall 1021 of an isolation layer 1019 between a first stack of nanosheets 1005 of the first field effect transistor 1003 and a second stack of nanosheets 1027 of the second field effect transistor 1025 and an isolation layer of an adjacent stacked field effect transistor structure 2051.

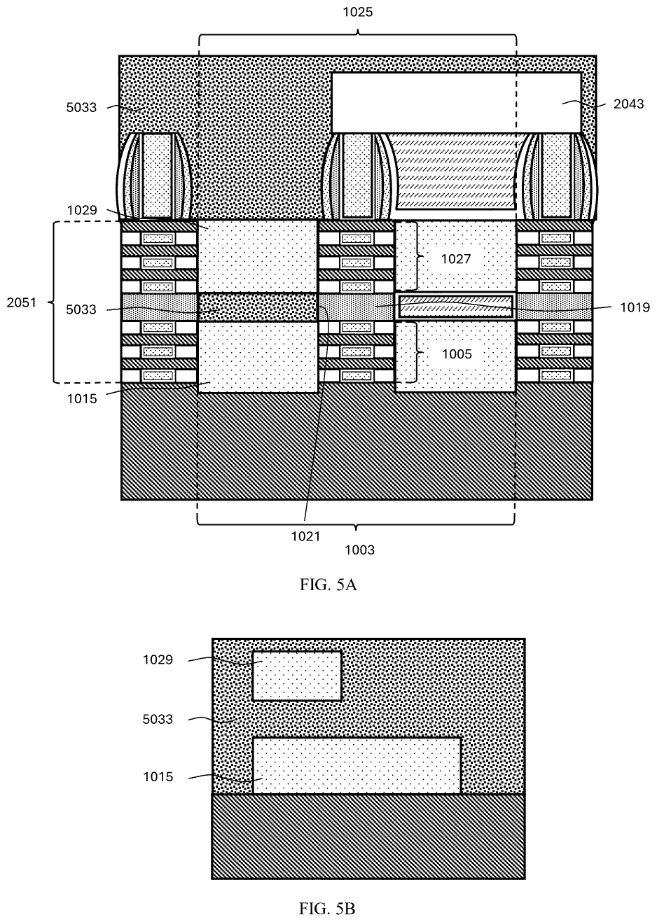

Continuing with FIGS. 5A and 5B, a cross-sectional view 1000 of a semiconductor structure, as shown in FIG. 1A, taken along line X-X′ and taken along line Y1-Y1′, respectively, during an intermediate operation of a method of fabricating the semiconductor structure, are illustrated. In some embodiments, a metalized embedded contact 5033 can be deposited over the semiconductor structure (e.g., semiconductor structure as referenced in FIGS. 4A and 4B). The metalized embedded contact 5033 can be deposited utilizing an ALD metal deposition process, though embodiments are not so limited, and any suitable deposition process can be contemplated. The metalized embedded contact 5033 can fill a gap (i.e., gap 4045 as described in reference to FIGS. 4A and 4B) between a first epitaxial layer 1015 of a first field effect transistor 1003 and a third epitaxial layer 1029 of a second field effect transistor 1025 stacked on the first field effect transistor 1003 and between a first sidewall 1021 of an isolation layer 1019 between a first stack of nanosheets 1005 of the first field effect transistor 1003 and a second stack of nanosheets 1027 of the second field effect transistor 1025 and an isolation layer of an adjacent stacked field effect transistor structure 2051. Accordingly, the metalized embedded contact 5033 can directly contact, without any intervening layers, the first epitaxial layer 1015 and the third epitaxial layer 1029, electrically connecting the first epitaxial layer 1015 to the third epitaxial layer 1029.

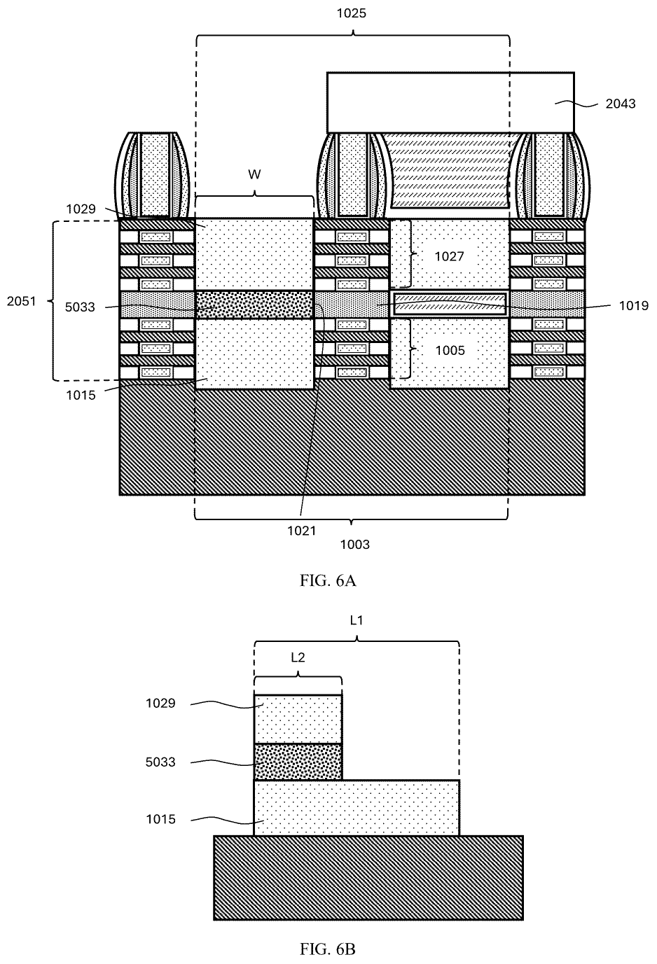

In a cross-sectional view 1000 of a semiconductor structure taken along line X-X′ and line Y1-Y1′, as shown in FIG. 1A, FIGS. 6A and 6B, respectively, illustrate an intermediate operation of a method of fabricating the semiconductor structure which can include selectively removing a metalized embedded contact 5033. The metalized embedded contact 5033 (e.g., metalized embedded contact 5033 as shown in FIGS. 5A and 5B) can be selectively removed utilizing processes known in the art, such as a metal RIE process, though embodiments are not so limiting. As shown in FIGS. 6A and 6B, remaining metalized embedded contact 5033 can fill a gap (i.e., gap 4045 as shown in FIGS. 4A and 4B) between a first epitaxial layer 1015 of a first field effect transistor 1003 and a third epitaxial layer 1029 of a second field effect transistor 1025 stacked on the first field effect transistor 1003 and between a first sidewall 1021 of an isolation layer 1019 between a first stack of nanosheets 1005 of the first field effect transistor 1003 and a second stack of nanosheets 1027 of the second field effect transistor 1025 and an isolation layer of an adjacent stacked field effect transistor structure 2051. As shown in FIG. 6B, in some embodiments, a length L1 of the first epitaxial layer 1015 can be greater than a length L2 of the third epitaxial layer 1029, though, as previously stated, embodiments are not so limiting. The metalized embedded contact 5033 can have a length similar to that of the length L2 of the third epitaxial layer 1029. Further, the metalized embedded contact 5033, in some embodiments, can have a width similar to a width W of the first epitaxial layer 1015 and the third epitaxial layer 1029. Advantageously, the metalized embedded contact 5033 can physically and electrically connect the first epitaxial layer 1015 to the third epitaxial layer 1029 without the use of vias and/or circuitry external (e.g., such as wiring levels or layers above and/or below the stacked field effect transistors) to the semiconductor structure. Further, utilizing the metalized embedded contact 5033, contact areas between the metalized embedded contact 5033 and the first epitaxial layer 1015 and between the metalized embedded contact 5033 and the third epitaxial layer 1029 can be significantly greater as compared to previous approaches. Accordingly, such contact areas can notably reduce contact resistance, in comparison to previous approaches.

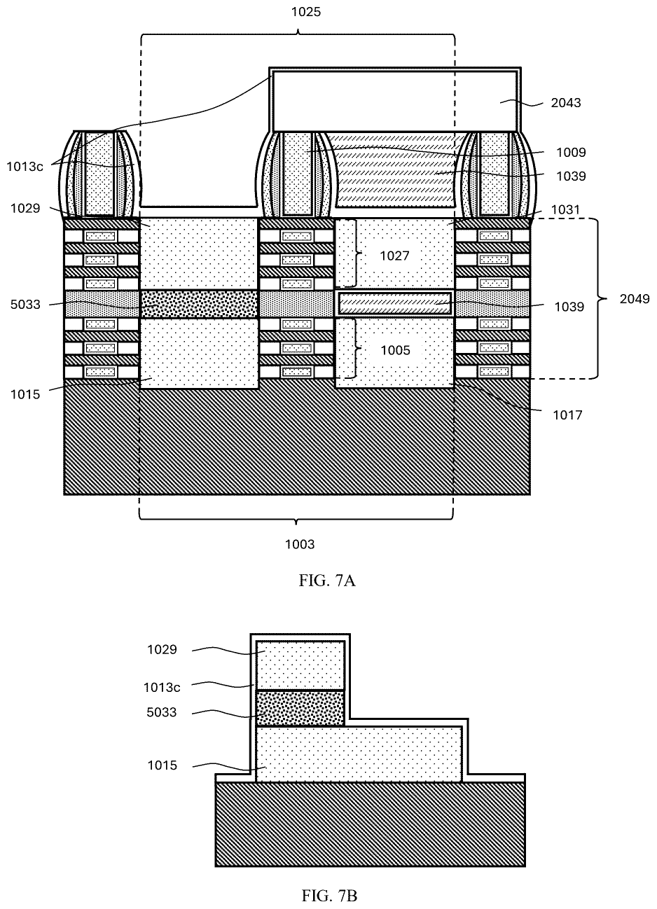

FIGS. 7A and 7B illustrate cross-sectional views 1000 of a semiconductor structure, as shown in FIG. 1A, taken along lines X-X′ and Y1-Y1′, respectively, during an intermediate operation of a method of fabricating the semiconductor structure. In some embodiments, spacer material can be deposited over the semiconductor structure (e.g., semiconductor structure as shown in FIGS. 6A and 6B) and selectively removed, using materials and processes similar to those described in reference to spacers 1013a in FIGS. 1B and 1C, forming spacers 1013c as shown in FIGS. 7A and 7B. Accordingly, spacers 1013c can cover a first epitaxial layer 1015 of a first field effect transistor 1003, a third epitaxial layer 1029 of a second field effect transistor 1025 stacked on the first field effect transistor 1003, and a metalized embedded contact 5033 between the first epitaxial layer 1015 and the third epitaxial layer 1029. Further, spacers 1013c can cover a mask 2043 located over a first stack of nanosheets 1005 and second epitaxial layer 1017 of the first field effect transistor 1003, a second stack of nanosheets 1027 and fourth epitaxial layer 1031 of the second field effect transistor 1025, a metal gate 1009 of the first stack of nanosheets 1005 and the second stack of nanosheets 1027, a first stack and second stack of nanosheets and a gate metal of an adjacent stacked field effect transistor structure 2049, and a first interlayer dielectric 1039 between the two stacked field effect transistor structures.

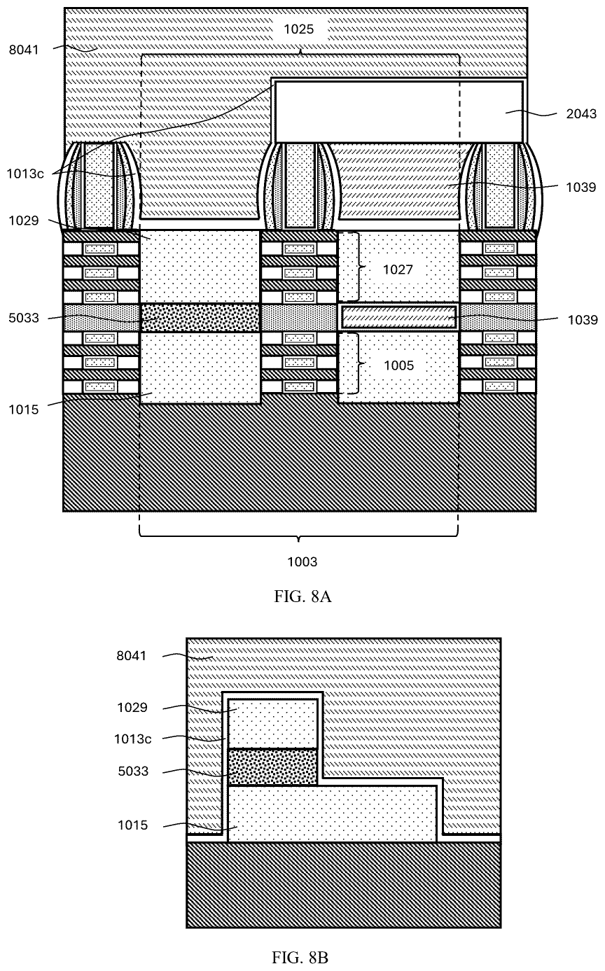

Moving to FIGS. 8A and 8B. FIG. 8A illustrates a cross-sectional view 1000 of a semiconductor structure as shown in FIG. 1A, taken along line X-X′, and FIG. 8B illustrates the cross-sectional view 1000 of the semiconductor structure as shown in FIG. 1A, taken along line Y1-Y1′, during an intermediate operation of a method of fabricating the semiconductor structure. The method of manufacturing the semiconductor, as shown in FIGS. 8A and 8B, can include depositing a second interlayer dielectric 8041 over the semiconductor structure (e.g., semiconductor structure as described in reference to FIGS. 7A and 7B). The second interlayer dielectric 8041 can be deposited over spacers 1013c (e.g., spacers 1013c as described in reference to FIGS. 8A and 8B). The second interlayer dielectric 8041 can be deposited utilizing processes and materials similar to those of a first interlayer dielectric 1039. In some embodiments, the second interlayer dielectric 8041 can be deposited utilizing an FCVD process, though embodiments are not so limited. Further, in some embodiments, the second interlayer dielectric 8041 can include the same material as the first interlayer dielectric 1039, though examples are not so limited and the second interlayer dielectric 8041 can include material different than the first interlayer dielectric 1039. In some non-limiting embodiments, the second interlayer dielectric 8041 can include SiO₂ or any suitable low-k dielectric material.

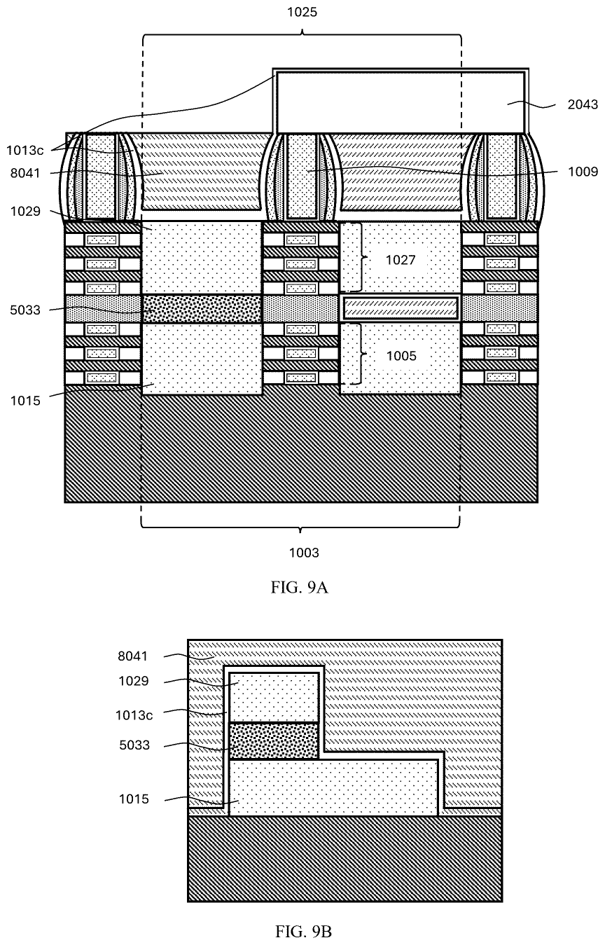

FIGS. 9A and 9B illustrate a cross-sectional view 1000 of a semiconductor structure as shown in FIG. 1A, taken along line X-X′ and line Y1-Y1′, respectively, during an intermediate operation of a method of fabricating the semiconductor structure. A second interlayer dielectric 8041, of the semiconductor structure as shown in FIGS. 8A and 8B, can be recessed to a top surface of a metal gate 1009 of a first field effect transistor 1003 and second field effect transistor 1025 stack, as shown in FIGS. 9A and 9B. In some non-limiting embodiments, the second interlayer dielectric 8041 can be recessed utilizing processes known in the art, such as an FCVD oxide recess, though embodiments are not so limited.

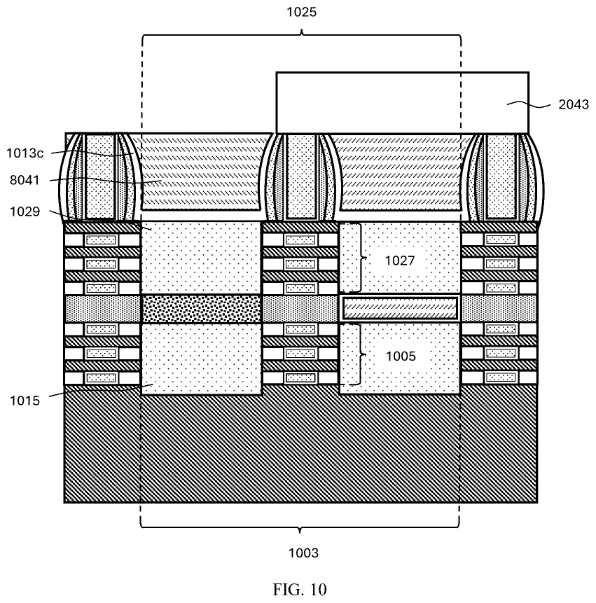

FIG. 10 illustrates a cross-sectional view 1000 of a semiconductor structure as shown in FIG. 1A, taken along line X-X′ during an intermediate operation of a method of fabricating the semiconductor structure. As illustrated in FIG. 10, a spacer (i.e., spacer 1013c as shown over mask 2043 in FIGS. 7A-9B) can be removed from a mask 2043 utilizing processes known in the art, such as, but not limited to, an RIE process.

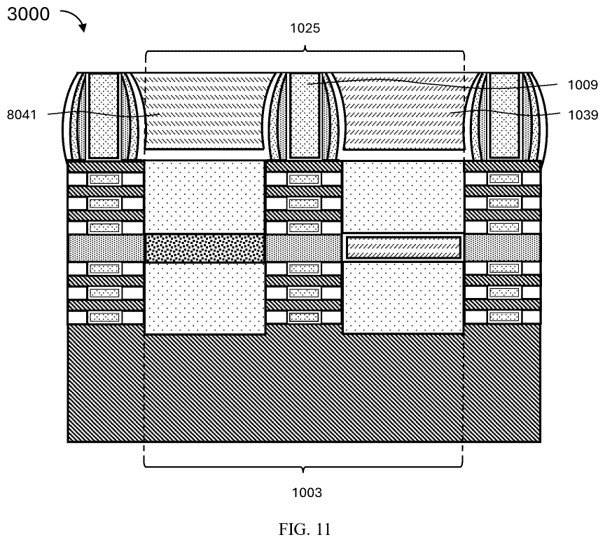

Continuing to FIG. 11, a cross-sectional view 1000 of a semiconductor structure 3000 as shown in FIG. 1A, taken along line X-X′, is illustrated. In some embodiments, a mask (i.e., mask 2043 as shown in FIGS. 2-11) can be removed. Further, in some embodiments, a second interlayer dielectric 8041 can be planarized to the top surface of a metal gate 1009 and a first interlayer dielectric 1039 of a first field effect transistor 1003 and a second field effect transistor 1025 of the semiconductor structure 3000, using, for example, a CMP process, though embodiments are not so limiting.

Turning now to FIGS. 12A-12C, an exemplary embodiment of a semiconductor structure 3000 is illustrated. FIG. 12A illustrates a cross-sectional view 1000 of the semiconductor structure 3000, as shown in FIG. 1A taken along the line X-X′. FIG. 12B illustrates a cross-sectional view 1000 of the semiconductor structure 3000, as shown in FIG. 1A taken along the line Y1-Y1′. FIG. 12C illustrates a cross-sectional view 1000 of the semiconductor structure 3000, as shown in FIG. 1A taken along the line Y2-Y2′.

Accordingly, FIGS. 12A and 12B illustrate the semiconductor structure 3000 including a metalized embedded contact 5033 sandwiched between and directly contacting (physically and electrically connecting) a first epitaxial layer 1015 of a first field effect transistor 1003 and a third epitaxial layer 1029 of a second field effect transistor 1025 of a stacked field effect transistor architecture structure. In some embodiments, the first epitaxial layer 1015 can be a source or a drain corresponding to a first stack of nanosheets 1005 of the first field effect transistor 1003 and the third epitaxial layer 1029 can be a source or a drain corresponding to a second stack of nanosheets 1027 of the second field effect transistor 1025. As such, the metalized embedded contact 5033 can physically and electrically connect the source or the drain of the first field effect transistor 1003 to the source or the drain of the second field effect transistor 1025. In some embodiments, a spacer 1013c can cover a stacked first epitaxial layer 1015, metalized embedded contact 5033, and third epitaxial layer 1029, and a portion of a metal gate 1009 extending from the second stack of nanosheets 1027 and a second interlayer dielectric 8041 can cover the spacer 1013c.

Similar to the semiconductor structure 2000 as described in reference to FIGS. 1B and 1C, semiconductor structure 3000 can further include nanosheets (i.e., semiconductor layers) 1007, surrounded by a gate dielectric 1011 and the metal gate 1009 that can extend through the second stack of nanosheets 1027 and the first stack of nanosheets 1005 and to a substrate 1001 of the semiconductor structure 3000. Further, in some embodiments, the nanosheets 1007 can be further separated by spacers 1013b and the first stack of nanosheets 1005 and the second stack of nanosheets 1027 can be separated by an isolation layer 1019. In some embodiments, a first sidewall 1021 of the isolation layer 1019 can be adjacent to the metalized embedded contact 5033.

A second epitaxial layer 1017 can be located on a side of the first stack of nanosheets 1005 opposite the first epitaxial layer 1015 and a fourth epitaxial layer 1031 can be located on a side of the second stack of nanosheets 1027 opposite the third epitaxial layer 1029. In some embodiments, the second epitaxial layer 1017 can be a source or a drain corresponding to the first stack of nanosheets 1005 and the fourth epitaxial layer 1031 can be a source or a drain corresponding to the second stack of nanosheets 1027. For example, the first epitaxial layer 1015 can be the source and the second epitaxial layer 1017 can be the drain corresponding to the first stack of nanosheets 1005, or vice versa, and the third epitaxial layer 1029 can be the source and the fourth epitaxial layer 1031 can be the drain corresponding to the second stack of nanosheets 1027, or vice versa. The second epitaxial layer 1017, the fourth epitaxial layer 1031, a second sidewall 1023 of the isolation layer 1019, and a portion of the metal gate 1009 extending from the second stack of nanosheets 1027 can be covered by spacers 1013a. Further, a first interlayer dielectric 1039 can cover the spacers 1013a (e.g., covering the second epitaxial layer 1017 and surrounding the fourth epitaxial layer 1031). Further, in some non-limiting embodiments, and as shown in FIG. 12A, spacers 1013a and 1013c formed on the metal gate 1009 can further include a first layer 1035 and a second layer 1037, along with a third layer 1013a and 1013c, respectively, though examples of embodiments are not so limiting. Still further, in some embodiments, the semiconductor structure 3000 can be electrically isolated from other regions of the substrate 1001 by a shallow trench isolation region 1147, as illustrated in FIGS. 12B-12C, though embodiments are not so limiting.

As described herein, the semiconductor structure 3000 can be fabricated to form a stacked field effect transistor structure, such as a gate-all-around field-effect transistor, including the second field effect transistor 1025 stacked on the first field effect transistor 1003. The first epitaxial layer 1015 (i.e., the source or the drain) of the first field effect transistor 1003 can be physically and electrically connected to the third epitaxial layer 1029 (i.e., the source or the drain) of the second field effect transistor 1025 through the metalized embedded contact 5033, internal to the semiconductor structure 3000, as illustrated in FIGS. 12A and 12B. Accordingly, the semiconductor structure 3000 can include an asymmetrical, metalized embedded contact 5033 (i.e., the metalized embedded contact 5033 on one side of the stacked field effect transistor structure) fabricated prior to any middle-of-the-line (MOL) fabrication process.

Continuing on, vias can be formed in the semiconductor structure 3000, utilizing processes known in the art. For example, a first via 1153, as illustrated in FIG. 12B, can physically and electrically connect the third epitaxial layer 1029, metalized embedded contact 5033, and the first epitaxial layer 1015 to circuitry (not shown for simplicity) formed external to the semiconductor structure 3000. Further, as illustrated in FIG. 12C, the second epitaxial layer 1017 (i.e., drain or source) of the first field effect transistor 1003 can be physically and electrically connected to a second via 1155 and the fourth epitaxial layer 1031 (i.e., drain or source) of the second field effect transistor 1025 can be physically and electrically connected to a third via 1157. The second via 1155 and the third via 1157 can extend from the semiconductor structure 3000 to circuitry (not shown for simplicity) formed external to the semiconductor structure 3000. In some embodiments, the first via 1153, second via 1155, and third via 1157 can be connected to one or more wiring levels or layers above or below the semiconductor structure 3000. For example, the first via 1153, second via 1155, and/or third via 1157 can be connected to power, ground, control signals, etc. within one or more wiring layers above the semiconductor structure 3000 during an MOL fabrication process. Though a total of three vias are illustrated in FIGS. 12B and 12C, embodiments are not so limited and fewer or more than three vias can be contemplated. Further, though the first via 1153, the second via 1155, and the third via 1157, as shown in FIGS. 12B and 12C, extend above the semiconductor structure 3000 to connect to a wiring layer (i.e., one or more wiring layers) from a frontside of the semiconductor structure 3000, embodiments are not so limited and vias can be contemplated to extend below the semiconductor structure 3000 to connect to a wiring layer (i.e., one or more wiring layers) from a backside of the semiconductor structure 3000.

Therefore, as described above, by forming an asymmetrical, fully embedded, direct (i.e., without any intervening layers) metalized connection between a source/drain region 1015 of the first field effect transistor 1003 and a source/drain region 1029 of the second field effect transistor 1025, an exemplary method of making a stacked field effect transistor semiconductor structure 3000 can provide a reduction in an amount of metal and space utilized in the connection between the source/drain region 1015 of the first field effect transistor 1003 and the source/drain region 1029 of the second field effect transistor 1025, reducing parasitic capacitance, such as in Cell-to-Cell parasitics between logic designs, and an improving cell height scaling, over previous approaches. Further, as opposed to previous approaches, the metalized embedded contact 5033 as described in the above exemplary embodiments, can eliminate a removal (i.e., an etching process) of part of a source/drain region of a second field effect transistor to form a via from a source/drain of a first field effect transistor, through the source/drain of the second field effect transistor, to a wiring layer above the two stacked field effect transistors. Thus the above exemplary embodiments, as opposed to previous approaches, can increase the finalized source/drain region 1029 of the second field effect transistor 1025, and a contact area between the metalized embedded contact 5033 and the source/drain 1015 of the first field effect transistor 1003 and the second field effect transistor 1025, reducing contact resistance.

Although the overall fabrication methods and the structures formed thereby are entirely novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposition on a {100} orientated crystalline surface can take on a {100} orientation. In some embodiments of the invention, epitaxial growth and/or deposition processes can be selective to forming on semiconductor surface, and may or may not deposit material on exposed surfaces, such as silicon dioxide or silicon nitride surfaces.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having structures such as memory devices including magnetic tunnel junctions formed in accordance with one or more of the exemplary embodiments.

At least a portion of the techniques described above can be implemented in an integrated circuit. Forming integrated circuits, identical dies are typically fabricated in a repeated pattern on a surface of a semiconductor wafer. Each die includes a device described herein and can include other structures and/or circuits. The individual dies are cut or diced from the wafer, then packaged as an integrated circuit. One skilled in the art would know how to dice wafers and package die to produce integrated circuits.

For the sake of brevity, conventional techniques related to semiconductor device and integrated circuit (IC) fabrication may or may not be described in detail herein. By way of background; however, a more general description of the semiconductor device fabrication processes that can be utilized in implementing one or more embodiments of the present invention is provided. The described combination of operations and/or resulting structures of the present invention are unique. Thus, the unique combination of the operations described in connection with the fabrication of a semiconductor device, according to the present invention, utilize a variety of individually known physical and chemical processes performed on a semiconductor (e.g., silicon) substrate, some of which are described herein.

In general, the various processes used to form a microchip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and atomic layer deposition (ALD), among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of there-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators, and selectively doped regions are built up to form the final device.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The drawing figures, as discussed above, depict exemplary processing steps/stages in the fabrication of exemplary structures. It is to be appreciated that the various layers and/or regions shown in the accompanying figures may not be drawn to scale. Furthermore, one or more semiconductor layers of a type commonly used in such integrated circuit devices or other layers may not be explicitly shown in a given figure for ease of explanation. This does not imply that the semiconductor layer(s) or other layer(s) not explicitly shown are omitted in the actual integrated circuit device.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps can sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom,” “top,” “above,” “over,” “under,” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The phrase “selective to,” such as, for example, “a first element selective to a second element,” means that the first element can be etched and the second element can act as an etch stop. The term “conformal” (e.g., conformal layer) means that the thickness of the layer is substantially the same on all surfaces, or that the thickness variation is less than 15% of the nominal thickness of the layer.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

What is claimed is:

1. A semiconductor structure comprising:
a substrate;
a first field effect transistor located on the substrate, the first field effect transistor comprising a first stack of nanosheets, a metal gate, a first source/drain region, and a second source/drain region;
a second field effect transistor located on the first field effect transistor, the second field effect transistor comprising a second stack of nanosheets, the metal gate, a third source/drain region, and a fourth source/drain region; and
a metalized embedded contact sandwiched between the first source/drain region of the first field effect transistor and the third source/drain region of the second field effect transistor, the metalized embedded contact filling a gap between the first source/drain region and the third source/drain region.

2. The semiconductor structure of claim 1, wherein the metalized embedded contact:
directly contacts, without any intervening layers, the first source/drain region of the first field effect transistor and the third source/drain region of the second field effect transistor; and
electrically connects the first source/drain region of the first field effect transistor to the third source/drain region of the second field effect transistor.

3. The semiconductor structure of claim 1, wherein the first source/drain region of the first field effect transistor is a first drain, the second source/drain region of the first field effect transistor is a first source, the third source/drain region of the second field effect transistor is a second drain, and the fourth source/drain region of the second field effect transistor is a second source.

4. The semiconductor structure of claim 1, wherein the first source/drain region of the first field effect transistor is a first drain, the second source/drain region of the first field effect transistor is a first source, the third source/drain region of the second field effect transistor is a second source, and the fourth source/drain region of the second field effect transistor is a second drain.

5. The semiconductor structure of claim 1, wherein the first source/drain region of the first field effect transistor is a first source, the second source/drain region of the first field effect transistor is a first drain, the third source/drain region of the second field effect transistor is a second source, and the fourth source/drain region of the second field effect transistor is a second drain.

6. The semiconductor structure of claim 1, wherein the first field effect transistor is a first polarity and the second field effect transistor is a second polarity different than the first polarity.

7. The semiconductor structure of claim 1, wherein the first source/drain region has a length greater than the third source/drain region and the metalized embedded contact has a same width and length as the third source/drain region.

8. The semiconductor structure of claim 1, further comprising an isolation layer sandwiched between the first field effect transistor and the second field effect transistor.

9. The semiconductor structure of claim 8, wherein the metalized embedded contact is adjacent to and contacting a first sidewall of the isolation layer.

10. The semiconductor structure of claim 9, further comprising a first interlayer dielectric located adjacent to a second sidewall of the isolation layer and between the second source/drain region of the first field effect transistor and the fourth source/drain region of the second field effect transistor, wherein the second sidewall of the isolation layer is opposite the first sidewall of the isolation layer.

11. The semiconductor structure of claim 10, further comprising a spacer, wherein:
the spacer separates the first interlayer dielectric from the second sidewall of the isolation layer, the second source/drain region of the first field effect transistor, and the fourth source/drain region of the second field effect transistor; and
the first interlayer dielectric fills an area between the second source/drain region of the first field effect transistor and the fourth source/drain region of the second field effect transistor.

12. A semiconductor structure comprising:
a first field effect transistor including a first source/drain region, a second source/drain region, a first stack of nanosheets between the first source/drain region and the second source/drain region, and a metal gate surrounding the first stack of nanosheets;
a second field effect transistor located on the first field effect transistor, the second field effect transistor including a third source/drain region, a fourth source/drain region, a second stack of nanosheets between the third source/drain region and the fourth source/drain region, and the metal gate surrounding the second stack of nanosheets;
a metalized, fully embedded contact sandwiched between and directly contacting the first source/drain region of the first field effect transistor and the third source/drain region of the second field effect transistor, the metalized, fully embedded contact filling a gap between the first source/drain region and the third source/drain region;
a first interlayer dielectric located between the second source/drain region of the first field effect transistor and the fourth source/drain region of the second field effect transistor; and
an isolation layer sandwiched between the first stack of nanosheets and the second stack of nanosheets and between the metalized, fully embedded contact and the first interlayer dielectric,
wherein the first field effect transistor is a first polarity and the second field effect transistor is a second polarity different than the first polarity.

13. The semiconductor structure of claim 12, wherein the first source/drain region of the first field effect transistor is a drain of the first field effect transistor, the third source/drain region of the second field effect transistor is a drain of the second field effect transistor, and the metalized, fully embedded contact is sandwiched between and electrically connects the drain of the first field effect transistor and the drain of the second field effect transistor.

14. The semiconductor structure of claim 12, wherein:
the first source/drain region is one of a source and a drain of the first field effect transistor and the third source/drain region is another of a source and a drain of the second field effect transistor; and
the metalized, fully embedded contact is sandwiched between and electrically connects one of:
the source of the first field effect transistor and the drain of the second field effect transistor; and
the drain of the first field effect transistor and the source of the second field effect transistor.

15. The semiconductor structure of claim 12, wherein the first source/drain region of the first field effect transistor is a source of the first field effect transistor, the third source/drain region of the second field effect transistor is a source of the second field effect transistor, and the metalized, fully embedded contact is sandwiched between and electrically connects the source of the first field effect transistor and the source of the second field effect transistor.

16. A method for making a semiconductor structure comprising:
forming, on a substrate, a first field effect transistor, a second field effect transistor, and an isolation layer between the first field effect transistor and the second field effect transistor, wherein:
the first field effect transistor comprises a first source/drain region, a second source/drain region, a first stack of nanosheets between the first source/drain region and the second source/drain region, and a metal gate surrounding the first stack of nanosheets; and
the second field effect transistor comprises a third source/drain region, a fourth source/drain region, a second stack of nanosheets between the third source/drain region and the fourth source/drain region, and the metal gate surrounding the second stack of nanosheets;
depositing a spacer, the spacer surrounding the metal gate and covering:
a top surface of the first source/drain region and the second source/drain region;
sidewalls of the isolation layer; and
a surrounding of the third source/drain region and the fourth source/drain region;
depositing a first interlayer dielectric to fill a gap between the first source/drain region and the third source/drain region, a second gap between the second source/drain region and the fourth source/drain region, and an area above the third source/drain region and the fourth source/drain region;
removing, using a mask, the first interlayer dielectric and the spacer from the gap between the first source/drain region and the third source/drain region and surrounding the third source/drain region;
depositing a metalized material; and
selectively removing, using the mask and the third source/drain region, the metalized material, leaving a portion of the metalized material to form a metalized embedded contact between the first source/drain region and the third source/drain region.

17. The method of claim 16, wherein:
after the first interlayer dielectric and the spacer is removed from the gap between the first source/drain region and the third source/drain region, the gap is filled with the metalized embedded contact, wherein the metalized embedded contact, without etching the first source/drain region nor the third source/drain region, directly connects, physically and electrically, the first source/drain region and the third source/drain region; and
the second gap between the second source/drain region and the fourth source/drain region is lined with the spacer and filled with the first interlayer dielectric.

18. The method of claim 16, further comprising depositing a second spacer on the top surface of the third source/drain region, a portion of the metal gate located above the second stack of nanosheets, and the mask.

19. The method of claim 18, further comprising depositing and etching a second interlayer dielectric to fill the area above the third source/drain region, wherein the second interlayer dielectric is a low-k dielectric.

20. The method of claim 19, further comprising removing the second spacer from the mask and removing the mask.
